(19) United States
(12) Patent Application Publication
(10) Pub. No.: US 2025/0006574 A1
(43) Pub. Date: Jan. 2, 2025

(54) REINFORCED SEMICONDUCTOR CHIP PRODUCTION METHOD, SEMICONDUCTOR CHIP WITH FILM, SEMICONDUCTOR CHIP REINFORCEMENT METHOD, REINFORCEMENT FILM AND SEMICONDUCTOR DEVICE

(71) Applicant: Resonac Corporation, Minato-ku, Tokyo (JP)

(72) Inventors: Takahiro KURODA, Minato-ku, Tokyo (JP); Kohei TANIGUCHI, Minato-ku, Tokyo (JP); Hiroki HASHIMOTO, Minato-ku, Tokyo (JP); Yoshinobu OZAKI, Minato-ku, Tokyo (JP); Keisuke OKAWARA, Minato-ku, Tokyo (JP)

(21) Appl. No.: 18/705,992

(22) PCT Filed: Nov. 5, 2021
(86) PCT No.: PCT/JP2021/040819

§ 371 Date: Apr. 30, 2024

(51) Int. Cl. H01L 23/29; H01L 21/56; H01L 23/31; H01L 23/488

(52) U.S. Cl. CPC H01L 23/293; H01L 21/56; H01L 23/3135; H01L 23/488

(57) ABSTRACT

A method for producing a reinforced semiconductor chip includes disposing a film having at least a thermosetting resin layer on a surface of a single-layer or multilayer semiconductor chip. A semiconductor device includes a substrate, a single-layer or multilayer semiconductor chip disposed on the substrate, and a cured product of a film including at least a thermosetting resin layer, the cured product being disposed on a surface of the semiconductor chip.

### DESCRIPTION

### Technical Field

The present disclosure relates to a method for producing a reinforced semiconductor chip, a film-attached semiconductor chip, a method for reinforcing a semiconductor chip, a reinforcement film, and a semiconductor device.

### Background Art

In recent years, as electronic instruments are becoming more multifunctional, application of stacked MCP (Multi Chip Package) in which a plurality of semiconductor chips are multilayered is in progress mainly in the field of memory semiconductor packages. As a memory semiconductor package to which stacked MCP is applied, for example, a three-dimensional NAND type memory is known (for example, Patent Literature 1).

### CITATION LIST

### Patent Literature

Patent Literature 1: WO 2020/013250 A1

### SUMMARY OF INVENTION

### Technical Problem

With regard to the above-described semiconductor package, higher speed, higher density, and high integration are also promoted, and along with this, semiconductor chips also become thinner. On the other hand, as semiconductor chips become thinner, problems such as warpage and cracking (cracks) of semiconductor chips may occur in the semiconductor packages. Such a tendency is remarkable in a semiconductor chip disposed at the top of semiconductor chips obtained by multilayering a plurality of semiconductor chips.

Thus, it is an object of the present disclosure to provide a novel method for producing a reinforced semiconductor chip.

### Solution to Problem

An aspect of the present disclosure relates to a method for producing a reinforced semiconductor chip. This method for producing a reinforced semiconductor chip includes disposing a film including at least a thermosetting resin layer, on a surface of a single layer or multilayer semiconductor chip. According to such a production method, it is possible to conveniently obtain a reinforced semiconductor chip.

The film may be a multilayer film. The multilayer film may be a film including a thermosetting resin layer and a rigid material layer having higher rigidity than the thermosetting resin layer. The multilayer film may be, for example, a film including a first thermosetting resin layer, a rigid material layer, and a second thermosetting resin layer in this order. In this case, the rigid material layer has higher rigidity than the first thermosetting resin layer and the second thermosetting resin layer. Here, rigidity means an ability of an object to withstand destruction against bending or twisting. Since the thermosetting resin layers have bonding adhesive properties to other members (for example, semiconductor chips), it is not necessary to separately provide a bonding adhesive layer or the like to the film. Incidentally, the rigidity after thermal curing of the thermosetting resin layer, the first thermosetting resin layer, and the second thermosetting resin layer may be lower or may be higher than the rigidity of the rigid material layer. In addition, the rigid material layer may be a resin rigid material layer having higher rigidity than the thermosetting resin layer, or a metal layer having higher rigidity than the thermosetting resin layer. The rigid material layer may be, for example, a polyimide resin layer.

The total thickness of the films (sum of the thicknesses of all the layers constituting the film) may be 5 to 180 μm.

Another aspect of the present disclosure relates to a film-attached semiconductor chip. This film-attached semiconductor chip includes: a single-layer or multilayer semiconductor chip; and a film including at least a thermosetting resin layer, the film being disposed on a surface of the semiconductor chip. According to such a film-attached semiconductor chip, it is possible to suppress problems such as warpage and cracking (cracks), which may occur in a semiconductor chip.

Another aspect of the present disclosure relates to a method for reinforcing a semiconductor chip. This method for reinforcing a semiconductor chip includes disposing a film including at least a thermosetting resin layer on a surface of a single-layer or multilayer semiconductor chip. According to such a method for reinforcing a semiconductor chip, it is possible to conveniently reinforce a semiconductor chip.

Another aspect of the present disclosure relates to a reinforcement film that is disposed on a surface of a single-layer or multilayer semiconductor chip to reinforce a semiconductor chip. This reinforcement film is a multilayer film including a first thermosetting resin layer, a rigid material layer, and a second thermosetting resin layer in this order. The rigid material layer has higher rigidity than the first thermosetting resin layer and the second thermosetting resin layer. According to such a reinforcement film, it is possible to suppress the occurrence of problems such as warpage and cracking (cracks) of semiconductor chips.

Another aspect of the present disclosure relates to a semiconductor device. This semiconductor device includes: a substrate; a single-layer or multilayer semiconductor chip disposed on the substrate; and a cured product of a film including at least a thermosetting resin layer, the cured product being disposed on a surface of the semiconductor chip.

### Advantageous Effects of Invention

According to the present disclosure, a novel method for producing a reinforced semiconductor chip is provided. Furthermore, according to the present disclosure, a film-attached semiconductor chip capable of suppressing problems such as warpage and cracking (cracks) that may occur in a semiconductor chip is provided. Furthermore, according to the present disclosure, a novel method for reinforcing a semiconductor chip, by which a semiconductor chip can be conveniently reinforced, is provided. According to the present disclosure, a reinforcement film that is used for such a method for reinforcing a semiconductor chip is provided. Furthermore, according to the present disclosure, a semiconductor device including a semiconductor chip is provided.

### BRIEF DESCRIPTION OF DRAWINGS

FIG. 1 is a cross-sectional view schematically illustrating a first embodiment of a semiconductor device.

FIG. 2A is a cross-sectional view schematically illustrating an embodiment of a film, FIG. 2B is a cross-sectional view schematically illustrating another embodiment of the film, and FIG. 2C is a cross-sectional view schematically illustrating another embodiment of the film.

FIG. 3A is a plan view schematically illustrating an embodiment of a laminated film including a raw film material for producing a film piece, and FIG. 2B is a cross-sectional view taken along line b-b in FIG. 2A.

FIG. 4A, FIG. 4B, FIG. 4C, and FIG. 4D are cross-sectional views schematically illustrating a production process for a film piece.

FIG. 5 is a cross-sectional view schematically illustrating a state in which the film is disposed on the surface of a semiconductor chip.

FIG. 6 is a cross-sectional view schematically illustrating an aspect of a second embodiment of the semiconductor device.

FIG. 7 is a cross-sectional view schematically illustrating another aspect of the second embodiment of the semiconductor device.

### DESCRIPTION OF EMBODIMENTS

Embodiments of the present disclosure will be described in detail below with reference to the drawings. However, the present invention is not intended to be limited to the following embodiments. Incidentally, the term “(meth)acrylic acid” as used in the present specification means acrylic acid or methacrylic acid, and the term “(meth)acrylate” means acrylate or methacrylate corresponding thereto.

The phrase “A or B” may include either A or B, or may include both of them.

The term “layer” as used in the present specification includes a structure having a shape formed over the entire surface as well as a structure having a shape formed on a part as observed in a plan view. Furthermore, the term “step” as used in the present specification includes not only an independent step but also includes a case where a step cannot be clearly distinguished from other steps, as long as the intended effect of the step is achieved. In addition, a numerical value range expressed by using the term “to” indicates a range including the numerical values described before and after the term “to” as the minimum value and the maximum value, respectively.

The content of each component in a composition according to the present specification means, in a case where a plurality of substances corresponding to each component are present in the composition, unless particularly stated otherwise, the total amount of the plurality of substances present in the composition. Regarding the materials mentioned as examples, unless particularly stated otherwise, one kind thereof may be used alone, or two or more kinds thereof may be used in combination. With regard to numerical value ranges described stepwise in the present specification, the upper limit value or lower limit value of a numerical value range of a certain stage may be replaced with the upper limit value or lower limit value of a numerical value range of another stage. Furthermore, with regard to a numerical value range described in the present specification, the upper limit value or lower limit value of the numerical value range may be replaced with a value indicated in the Examples.

### [Semiconductor Device]

### First Embodiment

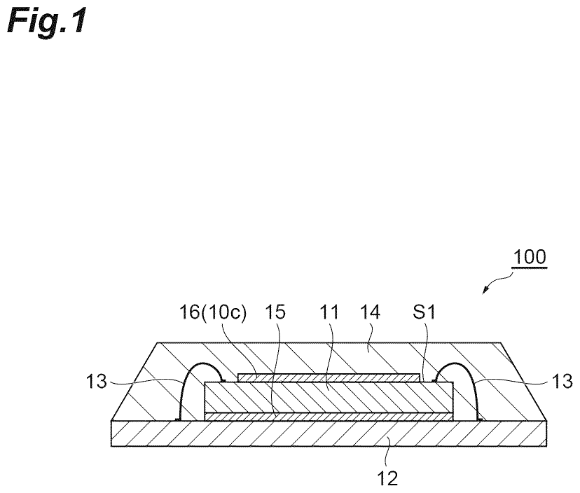

FIG. 1 is a cross-sectional view schematically illustrating a first embodiment of a semiconductor device. The first embodiment of the semiconductor device is a semiconductor device including a single-layer semiconductor chip. The semiconductor device 100 shown in FIG. 1 includes a substrate 12, a single-layer semiconductor chip 11 disposed on the substrate 12, and a reinforcement member 16 disposed on a surface S1 of the semiconductor chip 11. The reinforcement member 16 may be composed of a cured product 10c of a film having at least a thermosetting resin layer. The reinforcement member 16 is disposed so as to cover at least a partial region of the surface S1 of the semiconductor chip 11. From the viewpoint of work efficiency, it is preferable that the reinforcement member 16 is disposed so as to cover a partial region (region including a site where problems are likely to occur) of the surface S1 of the semiconductor chip 11. The semiconductor chip 11 and the substrate 12 are adhered through a bonding adhesive member 15 provided between the semiconductor chip 11 and the substrate 12. The bonding adhesive member 15 is usually composed of a cured product of a bonding adhesive composition. A connection terminal of the semiconductor chip 11 (not shown in the drawing) is electrically connected to an external connection terminal (not shown in the drawing) through a wire 13 and is sealed by a sealing material 14.

In the present embodiment, by disposing the reinforcement member 16 so as to cover at least a partial region of the surface S1 of the semiconductor chip 11, problems such as warpage and cracking (cracks) of the semiconductor chip 11 in the semiconductor package can be suppressed.

The substrate 12 may be an organic substrate or may be a metal substrate such as a lead frame. The thickness of the substrate 12 is, for example, 90 to 300 μm and may be 90 to 210 μm.

The semiconductor chip 11 is adhered to the substrate 12 through the bonding adhesive member 15 (cured product of a bonding adhesive composition). The shape of the semiconductor chip 11 when viewed in a plan view may be, for example, a rectangular shape (a square shape or an oblong shape). The length of one side of the semiconductor chip 11 is, for example, 20 mm or less and may be 4 to 20 mm or 4 to 12 mm. The thickness of the semiconductor chip 11 is, for example, 10 to 170 μm and may be 20 to 120 μm.

The reinforcement member 16 is disposed on the surface S1 of the semiconductor chip 11 and accomplishes a role of suppressing the occurrence of problems such as warpage and cracking (cracks) in the semiconductor chip 11. The reinforcement member 16 may be composed of a cured product 10c of a film having at least a thermosetting resin layer (or a cured product of a film piece that will be described below).

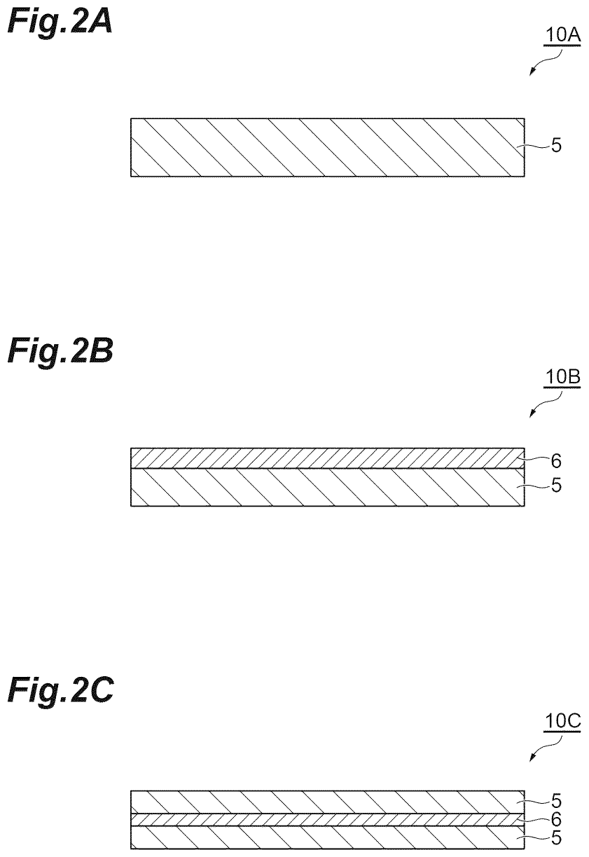

The film is a reinforcement film that is disposed on the surface of a semiconductor chip to reinforce the semiconductor chip. Such a film has at least a thermosetting resin layer. FIG. 2A is a cross-sectional view schematically illustrating an embodiment of the film, FIG. 2B is a cross-sectional view schematically illustrating another embodiment of the film, and FIG. 2C is a cross-sectional view schematically illustrating another embodiment of the film. A film 10A shown in FIG. 2A is a single-layer film composed of a thermosetting resin layer 5. A film 10B shown in FIG. 2B is a two-layer film having a thermosetting resin layer 5 and a rigid material layer 6 having higher rigidity than the thermosetting resin layer 5. A film 10C shown in FIG. 2C is a three-layer film having a first thermosetting resin layer (thermosetting resin layer 5), a rigid material layer 6, and a second thermosetting resin layer (thermosetting resin layer 5) in this order. In the film 10C, the rigid material layer 6 has higher rigidity than the first thermosetting resin layer and the second thermosetting resin layer. The first thermosetting resin layer and the second thermosetting resin layer may be identical with or different from each other. The film may be a multilayer film (film 10B or film 10C) and may be a film having the configuration of the film 10C. For example, in a case where the film is films 10A to 10C, a cured product 10c of the film is a product obtained after the thermosetting resin layer 5 included in the films 10A to 10C has been cured.

The thermosetting resin composition constituting the thermosetting resin layer 5 is a material that can go through a semi-cured (B-stage) state and then enter a completely cured product (C-stage) state by a subsequent curing treatment. The thermosetting resin composition contains an epoxy resin, an epoxy resin curing agent, and an elastomer and may further contain an inorganic filler, a curing accelerator, and the like as necessary.

### (Epoxy Resin)

The epoxy resin is not particularly limited as long as it is cured and acquires an adhesive action. Examples of the epoxy resin include bifunctional epoxy resins such as a bisphenol A type epoxy resin, a bisphenol F type epoxy resin, and a bisphenol S type epoxy resin; and novolac type epoxy resins such as a phenol novolac type epoxy resin and a cresol novolac type epoxy resin. In addition, generally known epoxy resins such as a multifunctional epoxy resin, a glycidyl amine type epoxy resin, a heterocyclic ring-containing epoxy resin, and an alicyclic epoxy resin can also be applied. These may be used singly, or two or more kinds thereof may be used in combination.

### (Epoxy Resin Curing Agent)

Examples of the epoxy resin curing agent include a phenol resin, an ester compound, an aromatic amine, an aliphatic amine, and an acid anhydride. Among these, from the viewpoint of achieving high adhesive strength, the epoxy resin curing agent may be a phenol resin. Examples of a commercially available product of the phenol resin include LF-4871 (trade name, BPA novolac type phenol resin) manufactured by DIC Corporation, HE-100C-30 (trade name, phenyl aralkyl type phenol resin) manufactured by AIR WATER INC., PHENOLITE KA and TD Series manufactured by DIC Corporation, MILEX XLC and XL Series (for example, MILEX XLC-LL) manufactured by Mitsui Chemicals, Inc., HE Series (for example, HE100C-30) manufactured by AIR WATER, INC., MEHC-7800 Series (for example, MEHC-7800-4S) manufactured by Meiwa Plastic Industries, Ltd., JDPP Series manufactured by JEF Chemical Corporation, and PSM Series (for example, PSM-4326) manufactured by Gun Ei Chemical Industry Co., Ltd. These may be used singly, or two or more kinds thereof may be used in combination.

From the viewpoint of achieving high adhesive strength, it is preferable to adjust the blending ratio between the epoxy resin and the phenol resin such that the equivalent ratios between the epoxy equivalent and the hydroxy group equivalent are 0.6 to 1.5, 0.7 to 1.4, or 0.8 to 1.3, respectively. When the blending ratio is within such ranges, both curability and fluidity tend to be easily achieved to sufficiently high levels.

The total content of the epoxy resin and the epoxy resin curing agent may be 5 to 40% by mass or 10 to 30% by mass based on the total amount of the thermosetting resin composition.

### (Elastomer)

Examples of the elastomer include an acrylic resin, a polyester resin, a polyamide resin, a polyimide resin, a silicone resin, polybutadiene, acrylonitrile, epoxy-modified polybutadiene, maleic anhydride-modified polybutadiene, phenol-modified polybutadiene, and carboxy-modified acrylonitrile.

From the viewpoint of achieving high adhesive strength, the elastomer may be an acrylic resin. The acrylic resin may be an epoxy group-containing (meth)acrylic copolymer obtained by polymerizing a functional monomer having an epoxy group (or a glycidyl group) as a crosslinkable functional group, such as glycidyl (meth)acrylate. The acrylic resin may also be an epoxy group-containing acrylic rubber. An epoxy group-containing acrylic rubber is a rubber having an epoxy group, which contains an acrylic acid ester as a main component and is formed of mainly a copolymer of butyl acrylate, acrylonitrile, and the like, or a copolymer of ethyl acrylate, acrylonitrile, and the like. The acrylic resin may have a crosslinkable functional group such as an alcoholic or phenolic hydroxyl group or a carboxyl group, in addition to an epoxy group.

Examples of a commercially available product of the acrylic resin include SG-70L, SG-708-6, WS-023 EK30, SG-280 EK23, and SG-P3 solvent-modified product (trade name, acrylic rubber, weight average molecular weight: 800000, Tg: 12° C., solvent is cyclohexanone) manufactured by Nagase ChemteX Corporation.

The glass transition temperature (Tg) of the elastomer (acrylic resin) may be −50 to 50° C. or-30 to 30° C., from the viewpoint of achieving high adhesive strength. Here, the glass transition temperature (Tg) means a value measured by using a DSC (thermal differential scanning calorimeter) (for example, “Thermo Plus 2” manufactured by Rigaku Corporation). The weight average molecular weight (Mw) of the elastomer (acrylic resin) may be 100000 to 3000000 or 500000 to 2000000, from the viewpoint of achieving high adhesive strength. Here, the Mw means a value measured by gel permeation chromatography (GPC) and converted by using a calibration curve based on polystyrene standards. Incidentally, a highly elastic film can be formed by using an elastomer (acrylic resin) having a narrow molecular weight distribution.

From the viewpoint of achieving high adhesive strength, the content of the elastomer (acrylic resin) may be 50 to 400 parts by mass or 100 to 400 parts by mass, with respect to a total of 100 parts by mass of the epoxy resin and the epoxy resin curing agent.

### (Inorganic Filler)

Examples of the inorganic filler include aluminum hydroxide, magnesium hydroxide, calcium carbonate, magnesium carbonate, calcium silicate, magnesium silicate, calcium oxide, magnesium oxide, aluminum oxide, aluminum nitride, aluminum borate whiskers, boron nitride, crystalline silica, and amorphous silica. These may be used singly, or two or more kinds thereof may be used in combination.

From the viewpoint of achieving high adhesive strength, the average particle size of the inorganic filler may be 0.005 to 1.0 μm or 0.05 to 0.5 μm. From the viewpoint of achieving high adhesive strength, the surface of the inorganic filler may be chemically modified. Examples of the material for chemically modifying the surface of the inorganic filler include a silane coupling agent. Examples of the type of the functional group of the silane coupling agent include a vinyl group, an acryloyl group, an epoxy group, a mercapto group, an amino group, a diamino group, an alkoxy group, and an ethoxy group.

From the viewpoint of achieving high adhesive strength, the content of the inorganic filler may be 1 to 100 parts by mass or 3 to 50 parts by mass with respect to 100 parts by mass of the resin component in the thermosetting resin composition.

### (Curing Accelerator)

Examples of the curing accelerator include imidazoles and derivatives thereof, organic phosphorus-based compounds, secondary amines, tertiary amines, and quaternary ammonium salts. From the viewpoint of achieving high adhesive strength, the curing accelerator may be imidazoles and derivatives thereof. Examples of the imidazoles include 2-methylimidazole, 1-benzyl-2-methylimidazole, 1-cyanoethyl-2-phenylimidazole, and 1-cyanoethyl-2-methylimidazole. These may be used singly, or two or more kinds thereof may be used in combination.

From the viewpoint of achieving high adhesive strength, the content of the curing accelerator may be 0.04 to 3 parts by mass or 0.04 to 0.2 parts by mass with respect to a total of 100 parts by mass of the epoxy resin and the epoxy resin curing agent.

The thermosetting resin layer can be obtained by, for example, molding the thermosetting resin composition into a film shape. In the formation of the thermosetting resin layer, a varnish (resin varnish) of the thermosetting resin composition may be used. In the case of using a resin varnish, the thermosetting resin layer can be obtained by mixing or kneading an epoxy resin, an epoxy resin curing agent, an elastomer, and components that are added as necessary in a solvent to prepare a resin varnish, applying the obtained resin varnish on a support film, and removing the solvent by heating and drying the solvent.

The support film is not particularly limited as long as it can withstand the above-described heating and drying; however, for example, the support film may be a polyester film, a polypropylene film, a polyethylene terephthalate film, a polyimide film, a polyetherimide film, a polyethylene naphthalate film, or a polymethylpentene film. The support film may be a multilayer film combining two or more kinds, or may be a film whose surface has been treated with a silicone-based or silica-based mold release agent, or the like.

Mixing or kneading can be carried out by using a conventional dispersing machine such as a stirrer, a Raikai mixer, a three-roll, or a ball mill and appropriately combining these.

As a method of applying the resin varnish on the support film, a known method can be used, and examples thereof include a knife coating method, a roll coating method, a spray coating method, a gravure coating method, a bar coating method, or a curtain coating method can be used. Heating and drying is not particularly limited as long as it is performed under the conditions in which the solvent used is sufficiently volatilized; however, heating and drying can be performed at a temperature in the range of 50 to 150° C. for a time in the range of 1 to 30 minutes. Heating and drying can be carried out stepwise at different heating temperatures and different heating times.

The thickness of the thermosetting resin layer is arbitrarily adjusted such that the total thickness of the film (sum of the thicknesses of all the layers constituting the film) is 5 to 180 μm. The thickness of the thermosetting resin layer may be, for example, 5 μm or greater, 10 μm or greater, 20 μm or greater, or 30 μm or greater and may be 180 μm or less, 150 μm or less, 120 μm or less, 100 μm or less, or 80 μm or less.

The rigid material layer may be a resin rigid material layer or a metal layer. The resin rigid material layer is a layer composed of a resin having higher rigidity than the thermosetting resin layer. When a multilayer film has such a resin rigid material layer, rigidity of the film itself can be ensured, and after singularization is performed by dicing at the time of fabricating film pieces, excellent pickup properties can be achieved even without performing a thermosetting treatment of the thermosetting resin layer. The type of the resin constituting the resin rigid material layer is not particularly limited and can be arbitrarily selected. The type of the resin may be, for example, a polyimide resin, and the resin rigid material layer may be a polyimide resin layer. With regard to a film having a resin rigid material layer, the thickness of the resin rigid material layer may be, for example, 10 to 90 μm or 10 to 60 μm.

The metal layer is a layer composed of a metal having higher rigidity than the thermosetting resin layer. When the multilayer film has such a metal layer, rigidity of the film itself can be ensured, and after singularization is performed by dicing at the time of fabricating film pieces, excellent pickup properties can be achieved even without performing a thermosetting treatment of the thermosetting resin layer. The type of the metal constituting the metal layer is not particularly limited and can be arbitrarily selected. The type of the metal may be, for example, copper, nickel, titanium, stainless steel, or aluminum, and the metal layer may be a copper layer, a nickel layer, a titanium layer, a stainless steel layer, or an aluminum layer, or may be a copper layer or an aluminum layer. With regard to the film having a metal layer, the thickness of the metal layer may be, for example, 10 to 90 μm or 10 to 60 μm.

The rigid material layer may be a resin rigid material layer having higher rigidity than the thermosetting resin layer, or a metal layer having higher rigidity than the thermosetting resin layer. Here, rigidity can be based on various mechanical properties, and can be based on, for example, the tensile modulus. The tensile modulus can be measured according to, for example, K7161-1:2014.

The total thickness of the film (sum of the thicknesses of all the layers constituting the film) is, for example, 5 to 180 μm, may be 10 μm or greater, 20 μm or greater, or 30 μm or greater, and may be 150 μm or less, 120 μm or less, 100 μm or less, or 80 μm or less. When the total thickness of the film is 5 μm or greater, an effect of reinforcing a semiconductor chip tends to be sufficiently exhibited, and when the total thickness of the film is 180 μm or less, there is a tendency that the occurrence of warpage in the film (thermosetting resin layer) after curing can be prevented. In addition, generally there is a restriction on the height of the semiconductor device in the sealing step, and it may be difficult to use a reinforcement member that increases the height of the semiconductor device. When the total thickness of the film is 180 μm or less, there is a tendency that the height of such a semiconductor device is less likely to be restricted.

The shape of the film when viewed in a plan view is not particularly limited, and for example, the shape may be a rectangular shape (a square shape or an oblong shape). The length of one side of the film is, for example, 20 mm or less and may be 4 to 20 mm or 4 to 12 mm. It is preferable that the length of one side of the film is smaller than the length of one side of the semiconductor chip 11.

With regard to the film 10A, which is a single-layer film, the fabricated thermosetting resin layer 5 can be used as it is as the film. The film 10B, which is a two-layer film, can be obtained by, for example, laminating the thermosetting resin layer 5 on one surface of the rigid material layer 6. The film 10C, which is a three-layer film, can be obtained by, for example, laminating the thermosetting resin layer 5 on a surface of the rigid material layer 6, the surface being on the opposite side of the surface where the thermosetting resin layer 5 is laminated in the film 10B.

The film may be film piece obtained by singularizing a raw film material (a base film material or a parent film material). A method for producing a film piece includes, for example, the following step (A), step (B), and step (C).

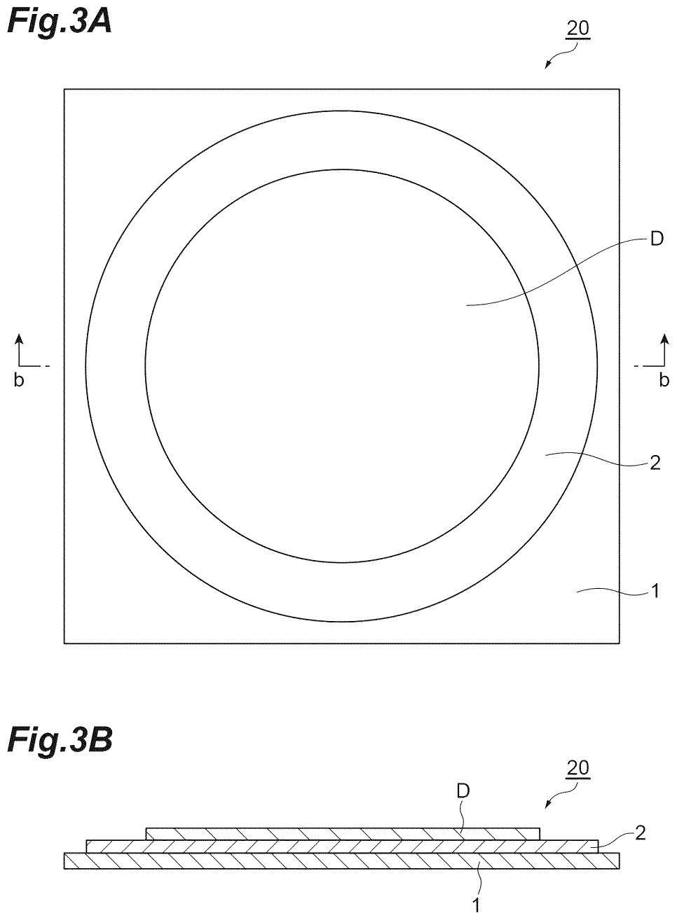

(A) preparing a laminated film 20 including a base material film 1, an adhesive layer 2, and a raw film material D having at least a thermosetting resin layer in this order (see FIG. 3).

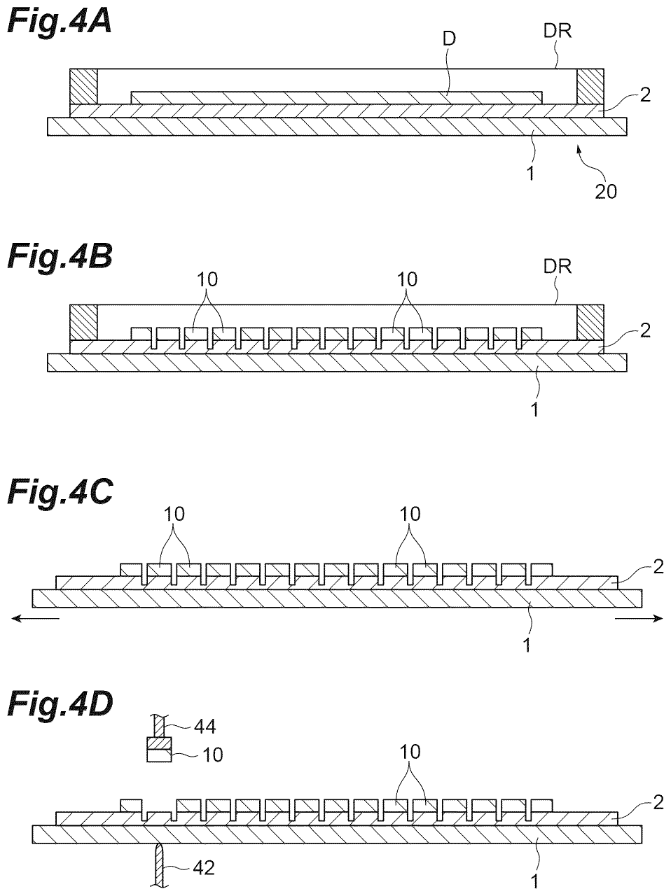

(B) forming a plurality of film pieces (film 10) on the surface of the adhesive layer 2 by singularizing the raw film material D (see FIG. 4B and FIG. 4C).

(C) picking up the film pieces (film 10) from the adhesive layer 2 (see FIG. 4C).

The reinforcement member 16 (cured product 10c of the film) shown in FIG. 1 is a product obtained after the thermosetting resin layer (thermosetting resin composition) included in the reinforcement member 16 has been cured. On the other hand, the film pieces (film 10) shown in FIG. 4B are products in a state before the thermosetting resin layer (thermosetting resin composition) included in the film pieces is completely cured.

### Step (A)

Step (A) is preparing a laminated film 20. The laminated film 20 includes a base material film 1, an adhesive layer 2, and a raw film material D having at least a thermosetting resin layer. The base material film 1 may be, for example, a polyethylene terephthalate film (PET film). The adhesive layer 2 is formed into a circular shape by punching or the like (see FIG. 3A). The adhesive layer 2 may be formed of a pressure-sensitive adhesive or may be formed of an ultraviolet-curable adhesive. In a case where the adhesive layer 2 is formed of an ultraviolet-curable adhesive, the adhesive layer 2 has a property in which the adhesive property is decreased when irradiated with ultraviolet radiation. The raw film material D is formed into a circular shape by punching or the like and has a smaller diameter than the adhesive layer 2 (see FIG. 3A). The raw film material D has a configuration having at least a thermosetting resin layer as is the case of the film 10 and has, for example, a configuration similar to those of the films 10A to 10C.

The thickness of the laminated film 20 may be, for example, 5 to 270 μm or 20 to 210 μm.

The laminated film 20 can be fabricated by, for example, bonding together a first laminated film having a base material film 1 and an adhesive layer 2 on the surface of the base material film 1, with a second laminated film having a cover film and a raw film material D on the surface of the cover film. The first laminated film is obtained through forming an adhesive layer on the surface of the base material film 1 by coating, and processing the adhesive layer into a predetermined shape (for example, a circular shape) by punching or the like. The second laminated film is obtained through forming the raw film material D on the surface of the cover film (for example, a PET film or a polyethylene film), and processing the raw film material D formed through the above-described step into a predetermined shape (for example, a circular shape) by punching or the like. On the occasion of using the laminated film 20, the cover film is peeled off at an appropriate timing.

### Step (B)

Step (B) is forming a plurality of film pieces on the surface of the adhesive layer 2 by singularizing the raw film material D. As shown in FIG. 4A, a dicing ring DR is stuck to the laminated film 20. That is, a dicing ring DR is stuck to the adhesive layer 2 of the laminated film 20, and the raw film material D is in a state of being disposed on the inner side of the dicing ring DR. The raw film material D is singularized by dicing (see FIG. 4B). For dicing, a dicing apparatus using a dicing saw can be used. As a result, a large number of film pieces (film 10) are obtained from the raw film material D.

### Step (C)

Step (C) is picking up the film pieces (film 10) from the adhesive layer 2. As shown in FIG. 4C, the film pieces are separated apart from each other by expanding the base material film 1. Next, as shown in FIG. 4C, the film pieces are peeled off from the adhesive layer 2 by pushing up the film pieces with a push-up tool 42, and at the same time, the film pieces are picked up by suctioning with a suction collet 44. Incidentally, a curing reaction of the thermosetting resin layer may be allowed to proceed by heating the raw film material D before dicing or the film pieces before being picked up. When the film pieces are moderately cured at the time of being picked up, excellent pickup properties can be achieved.

A method for producing a semiconductor device of the first embodiment includes, for example, the following step (D), step (E), and step (F).

(D) disposing a semiconductor chip 11 on a substrate 12.

(E) disposing a film 10 having at least a thermosetting resin layer on a surface S1 of the semiconductor chip 11.

(F) sealing the semiconductor chip 11 with a sealing material 14 (see FIG. 1).

### Step (D)

Step (D) is disposing a semiconductor chip 11 on a substrate 12. For example, first, a semiconductor chip 11 is disposed at a predetermined position on a substrate 12, with a bonding adhesive member 15 interposed therebetween. Thereafter, the semiconductor chip 11 is electrically connected to the substrate 12 using wires 13.

### Step (E)

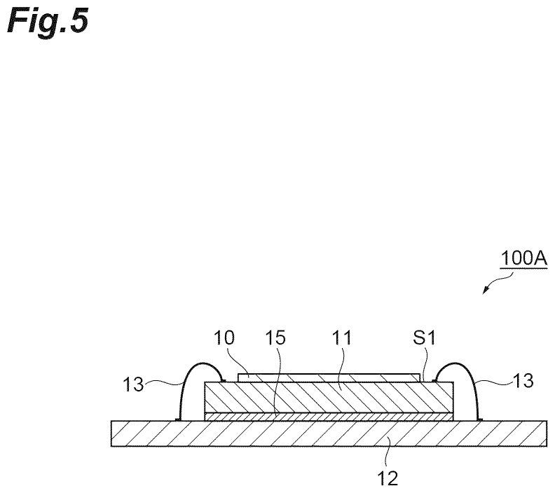

Step (E) is disposing a film 10 having at least a thermosetting resin layer on a surface S1 of the semiconductor chip 11. Through this step, a structure 100A shown in FIG. 5 is obtained. The structure 100A includes a substrate 12, a semiconductor chip 11 disposed on the surface of the substrate 12, and a film 10 disposed on the surface S1 of the semiconductor chip 11. Disposition of the film 10 can be performed by, for example, a pressure-bonding treatment. The pressure-bonding treatment can be carried out, for example, under the conditions of 80 to 180° C. and 0.01 to 0.50 MPa for 0.5 to 3.0 seconds. It is preferable that the thermosetting resin layer included in the film 10 is completely cured at a time point prior to the initiation of the step (F) to become a cured product 10c of the film. The cured product 10c of the film can be obtained by, for example, subjecting the film 10 to thermocompression bonding under the conditions of 80 to 180° C. and 0.01 to 1.0 MPa for 1 hour or longer.

### Step (F)

Step (F) is sealing the semiconductor chip 11 with a sealing material 14. Through this step, the semiconductor device 100 shown in FIG. 1 can be obtained.

### Second Embodiment

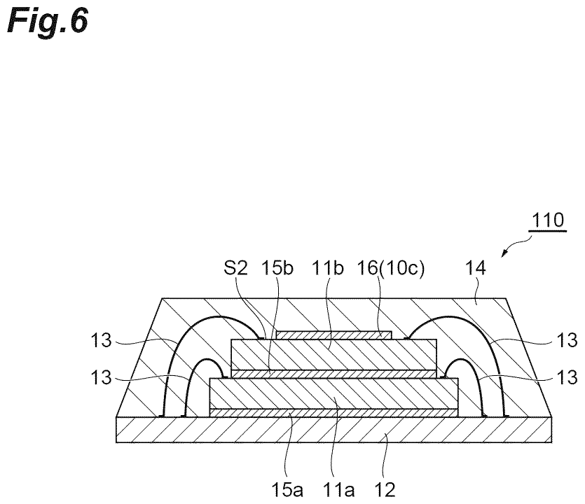

FIG. 6 is a cross-sectional view schematically illustrating an aspect of a second embodiment of the semiconductor device. The second embodiment of the semiconductor device is a semiconductor device including a multilayer (two or more layers) semiconductor chip. The semiconductor device 110 shown in FIG. 6 includes a substrate 12, multilayer semiconductor chips (a first-stage semiconductor chip 11a and a second-stage semiconductor chip 11b) disposed on the substrate 12, and a reinforcement member 16 disposed on the surface of the semiconductor chips. More specifically, the semiconductor device 110 includes: a substrate 12; a first-stage semiconductor chip 11a disposed on the substrate 12; a second-stage semiconductor chip 11b disposed on the first-stage semiconductor chip 11a; and a reinforcement member 16 disposed on a surface S2 of the second-stage semiconductor chip 11b. The reinforcement member 16 may be composed of a cured product 10c of a film having at least a thermosetting resin layer. The reinforcement member 16 is disposed so as to cover at least a partial region of the surface S2 of the second-stage semiconductor chip 11b. From the viewpoint of work efficiency, it is preferable that the reinforcement member 16 is disposed so as to cover a partial region (region including a site where problems are likely to occur) of the surface S2 of the second-stage semiconductor chip 11b. Incidentally, the reinforcement member 16 may also be disposed in a region on the surface of the first-stage semiconductor chip 11a, where the second-stage semiconductor chip 11b is not disposed, in addition to the surface S2 of the second-stage semiconductor chip 11b, which is the uppermost stage. In the semiconductor device 110, the first-stage semiconductor chip 11a is adhered to the substrate 12, with a bonding adhesive member 15a interposed therebetween, and the second-stage semiconductor chip 11b is further adhered onto the first-stage semiconductor chip 11a, with a bonding adhesive member 15b interposed therebetween. The bonding adhesive member 15a and the bonding adhesive member 15b are usually cured products of a bonding adhesive composition. Connection terminals (not shown in the drawing) of the first-stage semiconductor chip 11a and the second-stage semiconductor chip 11b are electrically connected to external connection terminals through wires 13 and are sealed by a sealing material 14.

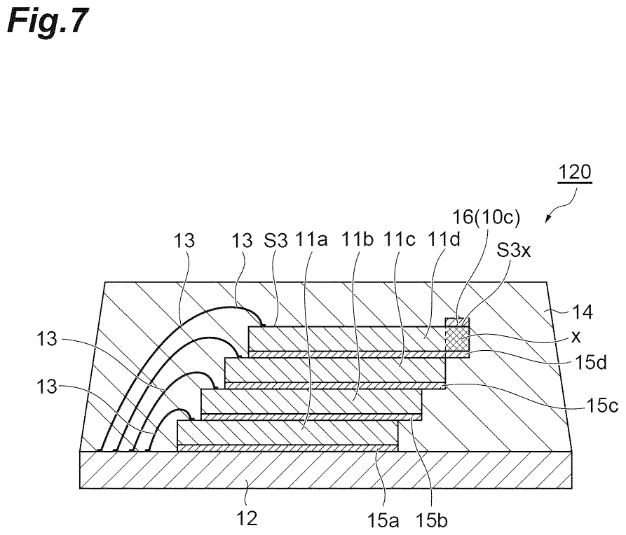

FIG. 7 is a cross-sectional view schematically illustrating another aspect of the second embodiment of the semiconductor device. The semiconductor device 120 shown in FIG. 7 includes a substrate 12, multilayer semiconductor chips (four semiconductor chips 11a, 11b, 11c, and 11d) disposed on the substrate 12, and a reinforcement member 16 disposed on the surface of the semiconductor chips. More specifically, the semiconductor device 120 includes: a substrate 12; semiconductor chips lla, 11b, 11c, and 11d disposed on the substrate 12; and a reinforcement member 16 disposed on a surface S3 of the semiconductor chip 11d. The four semiconductor chips 11a, 11b, 11c, and 11d are laminated at positions that are shifted from each other in the transverse direction (direction orthogonally intersecting the direction of lamination) for connection to the connection terminals (not shown in the drawing) formed on the surface of the substrate 12 (see FIG. 7). The reinforcement member 16 may be composed of a cured product 10c of a film having at least a thermosetting resin layer. The reinforcement member 16 is disposed so as to cover at least a partial region of a surface S3 of the semiconductor chip 11d. It is preferable that the reinforcement member 16 is disposed so as to cover a partial region of the surface S3 of the semiconductor chip 11d, from the viewpoint of work efficiency. In the semiconductor chip 11d, it is expected that problems such as cracking (cracks) are likely to occur in a portion (portion x in FIG. 7) that is not supported by the semiconductor chip 11c. Therefore, it is more preferable that the reinforcement member 16 is disposed in a region including a portion or the entirety of the surface S3x of the semiconductor chip 11d corresponding to a portion (portion x in FIG. 7) that is not supported by the semiconductor chip 11c (see FIG. 7). In addition to the surface S3 of the semiconductor chip 11d in the uppermost stage, the reinforcement member 16 may also be disposed in a region on the surface of the semiconductor chips 11a, 11b, and 11c, where the semiconductor chip is not disposed. In the semiconductor device 120, the substrate 12 and each of the semiconductor chips are adhered to each other through bonding adhesive members 15a, 15b, 15c, and 15d. The bonding adhesive members 15a, 15b, 15c, and 15d are usually cured products of a bonding adhesive composition. The semiconductor chips lla, 11b, 11c, and 11d are electrically connected to external connection terminals through wires 13 and are sealed by a sealing material 14.

The semiconductor device of the second embodiment can be obtained by, for example, a method further including laminating at least one semiconductor chip on the semiconductor chip 11 (step (D′)) between step (D) and step (E) in the above-described method for producing a semiconductor device of the first embodiment.

Thus, the semiconductor device (package) of the embodiments of the present disclosure has been described in detail; however, the present disclosure is not limited to the above-described embodiments. For example, in FIG. 7, a semiconductor device in a form in which four semiconductor chips are laminated has been described as an example; however, the number of semiconductor chips to be laminated is not limited to this. Furthermore, in FIG. 7, a semiconductor device in the form in which semiconductor chips are laminated at positions that are shifted from each other in the transverse direction (direction orthogonally intersecting the direction of lamination) has been mentioned as an example; however, a semiconductor device in the form in which semiconductor chips are laminated at positions that are not shifted from each other in the transverse direction (direction orthogonally intersecting the direction of lamination), is also acceptable.

### [Method for Producing Reinforced Semiconductor Chip]

A method for producing a reinforced semiconductor chip of an embodiment includes disposing a film having at least a thermosetting resin layer on a surface of a single-layer or multilayer semiconductor chip. According to such a production method, it is possible to conveniently obtain a reinforced semiconductor chip.

Disposing a film having at least a thermosetting resin layer on the surface of a single-layer or multilayer semiconductor chip is similar to step (E) in the above-described method for producing a semiconductor device. Incidentally, the film and semiconductor chip used in the method for reinforcing a semiconductor chip are similar to the film and semiconductor chip used in the above-described semiconductor device. Therefore, any duplicate description will not be repeated here.

### [Film-Attached Semiconductor Chip]

A film-attached semiconductor chip of an embodiment includes a single-layer or multilayer semiconductor chip and a film having at least a thermosetting resin layer, the film being disposed on a surface of the semiconductor chip. According to such a film-attached semiconductor chip, it is possible to suppress problems such as warpage and cracking (cracks) that may occur in the semiconductor chip.

The film-attached semiconductor chip can be obtained by a production method including a step similar to step (E) in the above-described method for producing a semiconductor device. Incidentally, the film and semiconductor chip in the film-attached semiconductor chip are similar to the film and semiconductor chip used in the above-described semiconductor device. Therefore, any duplicate description will not be repeated here.

### [Method for Reinforcing Semiconductor Chip]

A method for reinforcing a semiconductor chip of an embodiment includes disposing a film having at least a thermosetting resin layer on a surface of a single-layer or multilayer semiconductor chip. According to such a method for reinforcing a semiconductor chip, it is possible to conveniently reinforce a semiconductor chip.

Disposing a film having at least a thermosetting resin layer on a surface of a single-layer or multilayer semiconductor chip is similar to step (E) in the above-described method for producing a semiconductor device. Incidentally, the film and semiconductor chip in the method for reinforcing a semiconductor chip are similar to the film and semiconductor chip used in the above-described semiconductor device. Therefore, any duplicate description will not be repeated here.

### [Reinforcement Film]

A reinforcement film of an embodiment is a film that is disposed on a surface of a single-layer or multilayer semiconductor chip and used to reinforce a semiconductor chip. The reinforcement film is a multilayer film having a first thermosetting resin layer, a rigid material layer, and a second thermosetting resin layer in this order. The rigid material layer has higher rigidity than the first thermosetting resin layer and the second thermosetting resin layer.

The reinforcement film of the present embodiment is similar to the film 10C shown in FIG. 2C in the above-described semiconductor device. Therefore, any duplicate description will not be repeated here.

### INDUSTRIAL APPLICABILITY

According to the present disclosure, a novel method for producing a reinforced semiconductor chip is provided. According to the present disclosure, a film-attached semiconductor chip capable of suppressing problems such as warpage and cracking (cracks) that may occur in a semiconductor chip is provided. Furthermore, according to the present disclosure, a novel method for reinforcing a semiconductor chip, by which a semiconductor chip can be conveniently reinforced, is provided. Furthermore, according to the present disclosure, a reinforcement film used in such a method for reinforcing a semiconductor chip is provided. In addition, according to the present disclosure, a semiconductor device including a semiconductor chip is provided.

### REFERENCE SIGNS LIST

1: base material film, 2: adhesive layer, 5: thermosetting resin layer, 6: rigid material layer, 10, 10A, 10B, 10C: film, 10c: cured product of film, 11, 11a, 11b, 11c, 11d: semiconductor chip, 12: substrate, 13: wire, 14: sealing material, 15, 15a, 15b, 15c, 15d: bonding adhesive member, 16: reinforcement member, 20: laminated film, 42: push-up tool, 44: suction collet, 100, 110, 120: semiconductor device, 100A: structure, D: raw film material, S1, S2, S3, S3x: surface.

1. A method for producing a reinforced semiconductor chip, the method comprising:
disposing a film comprising at least a thermosetting resin layer, on a surface of a single-layer or multilayer semiconductor chip.

2. The method for producing a reinforced semiconductor chip according to claim 1,
wherein the film is a multilayer film.

3. The method for producing a reinforced semiconductor chip according to claim 2,
wherein the multilayer film is a film comprising a thermosetting resin layer and a rigid material layer having higher rigidity than the thermosetting resin layer.

4. The method for producing a reinforced semiconductor chip according to claim 2,
wherein the multilayer film is a film comprising a rigid material layer located between a first thermosetting resin layer and a second thermosetting resin layer, and
the rigid material layer has higher rigidity than the first thermosetting resin layer and the second thermosetting resin layer.

5. The method for producing a reinforced semiconductor chip according to claim 3,
wherein the rigid material layer is a polyimide resin layer.

6. The method for producing a reinforced semiconductor chip according to claim 1,
wherein a total thickness of the film is 5 to 180 μm.

7. (canceled)

8. (canceled)

9. A reinforcement film to be disposed on a surface of a single-layer or multilayer semiconductor chip to reinforce a semiconductor chip,
the reinforcement film being a multilayer film comprising a rigid material layer located between a first thermosetting resin layer and a second thermosetting resin layer,
wherein the rigid material layer has higher rigidity than the first thermosetting resin layer and the second thermosetting resin layer.

10. A semiconductor device, comprising:
a substrate;
a single-layer or multilayer semiconductor chip disposed on the substrate; and
a cured product of a film comprising at least a thermosetting resin layer, the cured product being disposed on a surface of the semiconductor chip.

11. The semiconductor device according to claim 10,
wherein the film is a multilayer film.

12. The semiconductor device according to claim 11,
wherein the multilayer film is a film comprising the thermosetting resin layer and a rigid material layer having higher rigidity than the thermosetting resin layer.

13. The semiconductor device according to claim 11,
wherein the multilayer film is a film comprising a rigid material layer located between a first thermosetting resin layer and a second thermosetting resin layer, and
the rigid material layer has higher rigidity than the first thermosetting resin layer and the second thermosetting resin layer.

14. The semiconductor device according to claim 12, wherein the rigid material layer is a polyimide resin layer.
